(19) United States
(12) Patent Application Publication
(10) Pub. No.: US 2026/0090105 A1
(43) Pub. Date: Mar. 26, 2026

(54) Display Panel and Display Device

(71) Applicant: WUHAN CHINA STAR OPTOELECTRONICS TECHNOLOGY CO., LTD., Wuhan, Hubei (CN)

(72) Inventors: Tao MA, Wuhan, Hubei (CN); Xindong MEI, Wuhan, Hubei (CN); Dewei SONG, Wuhan, Hubei (CN); Shiyu LONG, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/567,379

(22) PCT Filed: Oct. 31, 2023
(86) PCT No.: PCT/CN2023/128758

§ 371 Date: Dec. 6, 2023

(30) Foreign Application Priority Data
Oct. 19, 2023 (CN) 202311361572.8

(51) Int. Cl. H10D 86/40; G02F 1/1339; G02F 1/1343; G02F 1/1362; G02F 1/1368; H10D 86/60

(52) U.S. Cl. CPC H10D 86/451; G02F 1/13394; G02F 1/13398; G02F 1/134309; G02F 1/136209; G02F 1/136222; G02F 1/136286; G02F 1/1368; H10D 86/60

(57) ABSTRACT

The present disclosure proposes a display panel and a display device. An array substrate includes a first spacer structure and a spacer layer arranged on a first substrate which is near the opposed substrate. A first opening is defined in the first spacer structure near the opposed substrate. A second spacer structure is filled in the first opening and protrudes from a surface of the spacer layer, which is near the opposed substrate. A support column is disposed between the opposed substrate and the second spacer structure, and a depth of the first opening is less than a thickness of the spacer layer.

### FIELD OF THE INVENTION

The present disclosure relates to the field of display technology, more particularly, to a display panel and a display device.

### BACKGROUND

A liquid crystal display (LCD) panel includes a color film substrate, a thin film transistor substrate, a liquid crystal sandwiched between the color film substrate and the thin film transistor substrate, and a sealant frame. The LCD panel also comprises a plurality of spacers to maintain box thickness.

However, due to the movement of the spacers during support or use, it is easy for the spacers to scratch the film layer inside the LCD panel, thereby affecting the display effect.

### SUMMARY

One embodiment of the present disclosure is directed to a display panel and a display device, which can avoid scratching a film layer on a support column and improve a yield rate of a second spacer structure.

An embodiment of the present disclosure provides a display panel comprising:
an array substrate;
an opposed substrate, arranged opposite to the array substrate; and
a support column, disposed between the array substrate and the opposed substrate;
wherein the array substrate comprises: a first substrate; a thin film transistor layer, arranged on one side of the first substrate near the opposed substrate; a first spacer structure, arranged on one side of the thin film transistor layer near the opposed substrate; a spacer layer, arranged on the side of the first spacer structure near the opposed substrate, wherein a first opening is defined in the spacer layer and located on the side of the first spacer structure near the opposed substrate; and a second spacer structure, filled in the first opening and protrudes from a surface of the spacer layer, which is near the opposed substrate. The support column is disposed between the opposed substrate and the second spacer structure, and a depth of the first opening is less than a thickness of the spacer layer.

Another embodiment of the present disclosure provides a display device comprising a backlight module and a display panel disposed on an emitting light side of the backlight module.

The display panel comprises:
an array substrate;
an opposed substrate, arranged opposite to the array substrate; and
a support column, disposed between the array substrate and the opposed substrate;
wherein the array substrate comprises: a first substrate; a thin film transistor layer, arranged on one side of the first substrate near the opposed substrate; a first spacer structure, arranged on one side of the thin film transistor layer near the opposed substrate; a spacer layer, arranged on the side of the first spacer structure near the opposed substrate, wherein a first opening is defined in the spacer layer and located on the side of the first spacer structure near the opposed substrate; and a second spacer structure, filled in the first opening and protrudes from a surface of the spacer layer, which is near the opposed substrate. The support column is disposed between the opposed substrate and the second spacer structure, and a depth of the first opening is less than a thickness of the spacer layer.

### BRIEF DESCRIPTION OF THE DRAWINGS

FIG. 1 is a structural schematic diagram of a display panel according to one embodiment of the present disclosure.

FIG. 2 is a size indication diagram corresponding to FIG. 1 according to one embodiment of the present disclosure.

FIG. 3 is another structural schematic diagram of the display panel according to one embodiment of the present disclosure.

FIG. 4 is a schematic diagram of a planar distribution of a plurality of sub-pixel regions in the display panel according to one embodiment of the present disclosure.

FIG. 5 is another structural schematic diagram of the display panel according to one embodiment of the present disclosure.

FIG. 6 is a size indication diagram corresponding to FIG. 5 according to one embodiment of the present disclosure.

FIG. 7 is another structural schematic diagram of the display panel according to one embodiment of the present disclosure.

### DESCRIPTION OF THE EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

The following disclosure provides many different embodiments or examples for implementing the various structures of the present disclosure. To simplify the disclosure of the present disclosure, the components and arrangements of specific examples are described below. Of course, they are merely examples and are not intended to limit the application. Furthermore, this application may repeat reference numbers and/or reference letters in different examples, such repetition being for the purposes of simplicity and clarity and does not by itself indicate a relationship between the various embodiments and/or arrangements discussed. In addition, this application provides examples of various specific processes and materials, but one of ordinary skill in the art will recognize the application of other processes and/or the use of other materials.

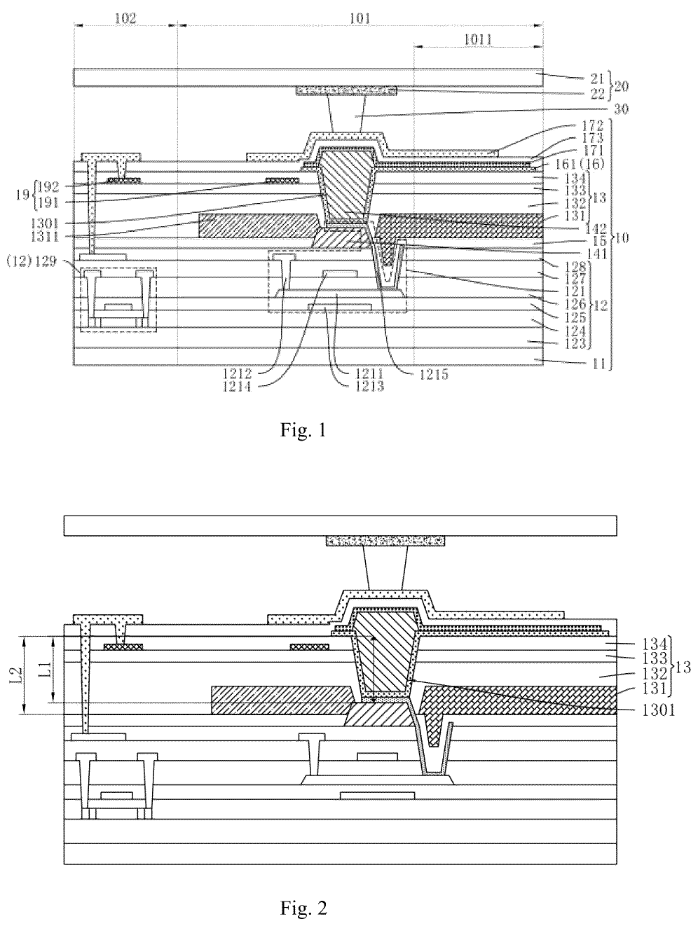

Please refer to FIG. 1 and FIG. 2. One embodiment of the present disclosure is directed to a display panel, which comprises an array substrate 10, an opposed substrate 20, and a support column 30.

The opposed substrate 20 is disposed opposite to the array substrate 10. The support column 30 is disposed between the array substrate 10 and the opposed substrate 20.

Furthermore, the array substrate 10 comprises a first substrate 11, a thin film transistor layer 12 located on one side of the first substrate 11 near the opposed substrate 20, a first spacer structure 141 located on one side of the thin film transistor layer 12 near the opposed substrate 20, a spacer layer 13 located on one side of the first spacer structure 141 near the opposed substrate 20, a first opening 1301 located in the spacer layer 13 and on one side of the first spacer structure 141 near the opposed substrate 20, and a second spacer structure 142. The second spacer structure 142 is filled with the first opening 1301 and protrudes from a surface of the spacer layer 13 near the opposed substrate 20. The support column 30 is disposed between the opposed substrate 20 and the second spacer structure 142. A depth L1 of the first opening 1301 is less than a thickness L2 of the spacer layer 13.

In the implementation and application process, the embodiment of the present disclosure forms a second spacer structure 142 protruding from the surface of the spacer layer 13 after forming the first opening 1301 of the spacer layer 13, and the second spacer structure 142 is correspondingly arranged with the support column 30. Therefore, the film layer around the second spacer structure 142 is further away from the support column 30 in a thickness direction of the display panel, which can avoid the support column 30 from scratching the film layer around the second spacer structure 142 due to movement, thereby ensuring a yield rate and display effect of the display panel. Furthermore, by setting a first spacer structure 141 below the first opening 1301, the embodiment of the present disclosure can make a depth L1 of the first opening 1301 less than the thickness L2 of the spacer layer 13, reduce the thickness of the second spacer structure 142 during film deposition, avoid the phenomenon of etching residue caused by the thickness of the second spacer structure 142 during film deposition, and further improve the yield rate of the display panel.

Specifically, please refer to FIGS. 1 to 3, in one embodiment of the present disclosure, the display panel comprises a relatively arranged array substrate 10 and an opposed substrate 20, a liquid crystal layer (not shown in the figure) disposed between the array substrate 10 and the opposed substrate 20, and a support column 30 disposed between the array substrate 10 and the opposed substrate 20, which is used to maintain a box thickness of the liquid crystal layer.

The array substrate 10 comprises a first substrate 11, a thin film transistor layer 12 arranged on the first substrate 11, a spacer layer 13 arranged on the thin film transistor layer 12, a first electrode layer 16 arranged on the spacer layer 13, a second electrode layer 171 arranged on the first electrode layer 16, an insulation layer 173 arranged on the second electrode layer 171, and a third electrode layer 172 arranged on the insulation layer 173, The opposed substrate 20 is located on the side of the third electrode layer 172 away from the first substrate 11.

Furthermore, the thin film transistor layer 12 comprises a plurality of thin film transistors arranged on the first substrate 11 and a plurality of spacer insulation layers covering the thin film transistor. Among them, the display panel comprises a display area 101 and a non-display area 102 adjacent to the display area 101. The thin film transistors comprise a first thin film transistor 121 and a second thin film transistor 122 arranged in the display area 101, as well as a third thin film transistor 129 arranged in the non-display area 102. Each of the spacer insulation layers comprises a first spacer layer insulation layer 123, a second spacer layer insulation layer 124, a third spacer layer insulation layer 125, a fourth spacer layer insulation layer 126, a fifth spacer layer insulation layer 127, and a sixth spacer layer insulation layer 128 arranged sequentially on the first substrate 11.

It is noted that the display panel provided in the embodiment of the present disclosure is suitable for low temperature polycrystalline oxide (LTPO) display panels, where the first thin film transistor 121 and the second thin film transistor 122 can be oxide thin film transistors, and the third thin film transistor 129 can be low-temperature polycrystalline silicon thin film transistors.

In one embodiment, the first thin film transistor 121 comprises a first gate 1213 set on the second spacer layer insulation layer 124 and covered by the third spacer layer insulation layer 125, a first active layer 1211 set on the third spacer layer insulation layer 125 and covered by the fourth spacer layer insulation layer 126, and a second gate 1214 set on the fourth spacer layer insulation layer 126 and covered by the fifth spacer layer insulation layer 127. The first source electrode 1212 and the first drain electrode 1215 are arranged on the fifth spacer layer insulation layer 127 and covered by the sixth spacer layer insulation layer 128. The first gate 1213 and the second gate 1214 are respectively located on the upper and lower sides of the first active layer 1211, and correspond to the channel area setting of the first active layer 1211. The first source 1212 and the first drain 1215 are respectively connected on both sides of the first active layer 1211, and the connection positions are located on opposite sides of the channel area.

The second thin film transistor 122 comprises a third gate 1223 located on the second spacer layer insulation layer 124 and covered by the third spacer layer insulation layer 125, a second active layer 1221 located on the third spacer layer insulation layer 125 and covered by the fourth spacer layer insulation layer 126, and a fourth gate 1224 located on the fourth spacer layer insulation layer 126 and covered by the fifth spacer layer insulation layer 127. A second source electrode 1222 and a second drain electrode 1225 are arranged on the fifth spacer layer insulation layer 127 and covered by the sixth spacer layer insulation layer 128. The third gate 1223 and the fourth gate 1224 are respectively located on the upper and lower sides of the second active layer 1221, and correspond to the channel area of the second active layer 1221. The second source 1222 and the second drain 1225 are connected to both sides of the second active layer 1221, and the connection positions are located on opposite sides of the channel area.

The spacer layer 13 comprises a color resistance layer 131 located on the side of the thin film transistor layer 12 away from the first substrate 11, a flat layer 132 covering the color resistance layer 131, a first spacer layer dielectric layer 133 located on the side of the flat layer 132 away from the color resistance layer 131, and a second spacer layer dielectric layer 134 located on the side of the first spacer layer dielectric layer 133 away from the flat layer 132.

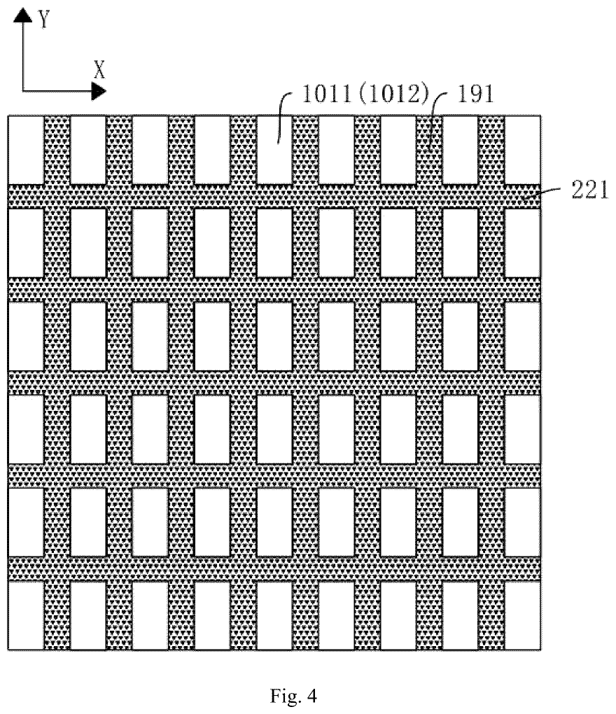

Please refer to FIGS. 1, 3, and 4. The display panel comprises a plurality of sub-pixel regions distributed within the display area 101, while the color blocking layer 131 comprises a plurality of color blocking blocks 1311 located within each sub-pixel region. In the embodiment of the present disclosure, the array substrate 10 further comprises a light blocking layer 19 located on one side away from the thin film transistor layer 12, a color blocking layer 131, a second substrate 21, and a black matrix layer 22 located on the side near the array substrate 10. The light blocking layer 19 also comprises a plurality of first light blocking portions 191 arranged in the first direction X and extending in the second direction Y, and the first direction X intersects with the second direction Y, The black matrix layer 22 comprises a plurality of second shading portions 221 arranged in the second direction Y and extending in the first direction X, and a plurality of first shading portions 191 and a plurality of second shading portions 221 intersect to define a plurality of sub-pixel regions. A plurality of sub-pixel regions can include a first sub-pixel region 1011 corresponding to the first thin film transistor 121, and a second sub-pixel region 1012 corresponding to the second thin film transistor 122.

In one embodiment of the present disclosure, the first direction X is perpendicular to the second direction Y.

In one embodiment of the present disclosure, the array substrate 10 also comprises a plurality of data lines arranged in the first direction X and extending in the second direction Y (as shown in the figure), as well as a plurality of scanning lines arranged in the second direction Y and extending in the first direction X (as shown in the figure), and a forward projection of the data lines on the first substrate 11 is located within a forward projection of the first shading portion 191 on the first substrate 11. A forward projection of the scanning line on the first substrate 11 is located within a forward projection of the second shading portion 221 on the first substrate 11. In the embodiment of the present disclosure, by setting the shading portions located between adjacent sub-pixel regions on the array substrate 10 and the opposed substrate 20 respectively, it is possible to avoid concentrated setting of the shading portions on the same film layer on the same substrate, thereby reducing spatial conflicts between film layer processes.

Specifically, in the corresponding first thin film transistor 121 and first sub-pixel region 1011, as shown in FIG. 1, the array substrate 10 further comprises a first spacer structure 141 and a third spacer layer dielectric layer 15 disposed between the thin film transistor layer 12 and the spacer layer 13, and the first spacer structure 141 protrudes from the surface of the third spacer layer dielectric layer 15 on one side away from the first substrate 11. The first spacer structure 141 is located on the side of the first thin film transistor 121 away from the first substrate 11, and the spacer layer 13 is arranged on the side of the first spacer structure 141 away from the first substrate 11.

A first opening 1301 is arranged in the spacer layer 13, and the first opening 1301 is located on the side of the first spacer structure 141 away from the first substrate 11. The bottom of the first opening 1301 exposes a portion of the upper surface of the first spacer structure 141. As the first spacer structure 141 is padded below the first opening 1301, the depth L1 of the first opening 1301 is less than the thickness L2 of the spacer layer 13. And the array substrate 10 also comprises a second spacer structure 142 located on the side away from the first substrate 11 of the first spacer structure 141, and the second spacer structure 142 is filled in the first opening 1301 and protrudes from the surface of the spacer layer 13 on the side away from the thin film transistor layer 12, that is, the second spacer structure 142 will form a protrusion on the surface of the second spacer layer dielectric layer 134 on the side away from the thin film transistor layer 12. The support column 30 is disposed between the second spacer structure 142 and the opposing substrate 20, and the film layer around the second spacer structure 142 is further away from the support column 30 in the thickness direction of the display panel. This can avoid the film layer around the second spacer structure 142 being scratched by the support column 30 due to movement, ensuring the yield and display effect of the display panel.

In one embodiment of the present disclosure, the materials of the first spacer structure 141 and the second spacer structure 142 both comprise organic materials and can be the same as the materials of the flat layer 132. The embodiment of the present disclosure sets the first spacer structure 141 below the first opening 1301, so that the depth L1 of the first opening 1301 is less than the thickness L2 of the spacer layer 13, reducing the depth L1 of the first opening 1301, and thus reducing the thickness of the second spacer structure 142 during membrane deposition, Avoiding the phenomenon of etching residue caused by the thickness of the second spacer structure 142 during film deposition, to ensure that the second spacer structure 142 can smoothly form a protrusion on the surface of the spacer layer 13 away from the thin film transistor layer 12, further improving the yield of the display panel.

Furthermore, one end of the first drain 1215 of the first thin film transistor 121 passes through the sixth spacer layer insulation layer 128, the fifth spacer layer insulation layer 127, and the fourth spacer layer insulation layer 126 and is connected to the first active layer 1211. The other end extends to the surface of the first spacer structure 141 far from the first substrate 11. The first electrode layer 16 comprises the first electrode 161, and one end of the first electrode 161 extends to the first opening 1301 and is connected to the first drain 1215, The other end extends into the first sub-pixel region 1011 corresponding to the first thin film transistor 121, which can be reused as a pixel electrode. And the second spacer structure 142 is filled with a portion of the first opening 1301, covering the first electrode 161 in the first opening 1301, that is, the second spacer structure 142 is located on the side of the first electrode 161 away from the first substrate 11.

It is noted that the color blocking block 1311 located in the first sub-pixel region 1011 is also filled in the contact hole between the first drain 1215 and the first active layer 1211 to avoid the appearance of a concave film layer morphology at the contact hole.

On the basis of filling the first opening 1301 with the second spacer structure 142 in the embodiment of the present disclosure to improve the morphology of the film layer, a convex boss protruding from the surface of the spacer layer 13 is synchronously formed using the second spacer structure 142, and the support column 30 is set at the corresponding position of the convex boss to avoid scratching the film layer of the array substrate 10 other than the convex boss due to movement of the support column 30. This means that the embodiment of the present disclosure also improves the yield rate of the display panel, The process of filling the first opening 1301 and forming a boss will also be combined. At the same time, the first opening 1301 is a contact hole between the first electrode 161 and the first drain 1215. Due to the flat layer 132 and color resistance layer 131 separated between the first electrode 161 and the first drain 1215, the contact hole needs to pass through a larger distance. However, a first spacer structure 141 is placed below the first opening 1301 to reduce the depth L1 of the first opening 1301, To avoid the residual phenomenon of the second spacer structure 142 during the etching process due to the large thickness that needs to be deposited, in the embodiment of the present disclosure, the first spacer structure 141 is arranged below the first opening 1301, the second spacer structure 142 is filled with the first opening 1301 and protrudes from the surface of the spacer layer 13, and the support column 30 is disposed between the second spacer structure 142 and the opposing substrate 20 in combination, Furthermore, on the basis of forming protrusions, it can effectively improve the yield and display effect of display panels.

As the resolution of the display panel increases, the available space in the display panel becomes smaller and the aperture of the contact hole between the drain and pixel electrode is also smaller, which increases the difficulty of etching. Therefore, in related technologies, incomplete etching of the contact hole or excessive etching may occur, resulting in the exposure of adjacent color resistance blocks 1311 in the contact hole. However, the embodiment of the present disclosure reduces the depth of the first opening 1301 by setting a first spacer structure 141, thereby reducing the depth of etching required in the flat layer 132. This can prevent incomplete or excessive etching of the first opening 1301 from exposing the color blocking block 1311 adjacent to the first opening 1301. In other words, the first opening 1301 in the embodiment of the present disclosure is set in the flat layer 132, the first spacer layer dielectric layer 133, and the second spacer layer dielectric layer 134. And set it in intervals with color blocking block 1311. This improves the yield rate of the display panel and enables the display panel provided in the embodiment of the present disclosure to achieve higher resolution.

In one embodiment of the present disclosure, the support column 30 is disposed between the black matrix layer 22 and the second spacer structure 142, and an orthogonal projection of the support column 30 on the first substrate 11 is located within an orthogonal projection of the black matrix layer 22 on the first substrate 11, and an orthogonal projection of the first opening 1301 on the first substrate 11, an orthogonal projection of the first spacer structure 141 on the first substrate 11. The forward projection of the second spacer structure 142 on the first substrate 11 is located within the forward projection of the black matrix layer 22 on the first substrate 11. The aperture of the first opening 1301 on one side near the first spacer structure 141 is smaller than the width of the first spacer structure 141 in a direction parallel to the first substrate 11.

In one embodiment of the present disclosure, the second electrode layer 171 is connected to the first electrode layer 16 and arranged opposite to the third electrode layer 172 to form a storage capacitor structure. Specifically, the second electrode layer 171 comprises a third electrode connected to the first electrode 161, and the first electrode 161 is connected to the third electrode, forming a storage capacitor structure with the third electrode layer 172. In the embodiment of the present disclosure, a second electrode layer 171 connected to the first electrode layer 16 is added, and the second electrode layer 171 is closer to the third electrode layer 172 compared to the first electrode layer 16, thereby enhancing the capacitance of the storage capacitor structure.

In addition, the first electrode 161 and the third electrode layer 172 are stacked as pixel electrodes, while the third electrode layer 172 is a common electrode. When the voltage is applied to the first electrode 161, the third electrode, and the third electrode layer 172, an electric field can be generated to control the deflection of liquid crystal molecules in the liquid crystal layer.

In one embodiment of the present disclosure, the material of the shading layer 19 is a conductive material, and the shading layer 19 also comprises a connecting portion 192 arranged in the non-display area 102. By switching wires in the non-display area 102 to input electrical signals to the connecting portion 192, the first shading portion 191 is loaded with electrical signals, which can release the static electricity generated in the array substrate 10 and load stable electrical signals to the first shading portion 191. To avoid interference with signal transmission in the array substrate 10 due to significant fluctuations in the electrical signal in the first shading section 191.

Optionally, a voltage signal loaded in the first shading section 191 is greater than or equal to −500 mA and less than or equal to 500 mA.

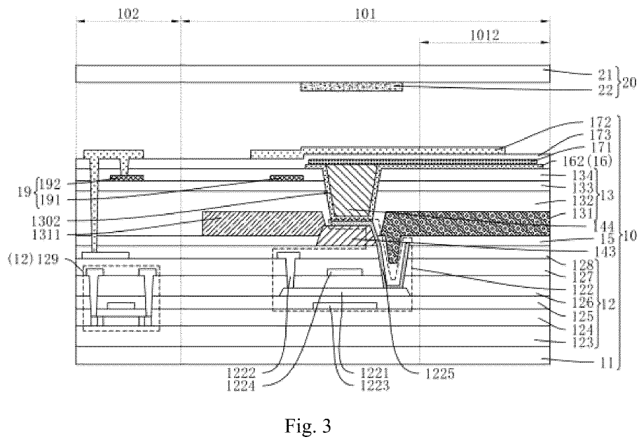

In addition, in the corresponding second thin film transistor 122 and a second sub-pixel region 1012, as shown in FIG. 3, the array substrate 10 further comprises a third spacer structure 143 located on the side of the second thin film transistor 122 away from the first substrate 11, a second opening 1302 located in the spacer layer 13 and on the side of the third spacer structure 143 away from the first substrate 11, and a fourth spacer structure 144.

It is noted that the second opening 1302 is arranged in the flat layer 132 and separated from the color resistance block 1311, and the depth L1 of the second opening 1302 is less than the thickness L2 of the spacer layer 13. The fourth spacer structure 144 is filled in the second opening 1302, and the side of the fourth spacer structure 144 far from the thin film transistor layer 12 does not exceed the surface of the side of the spacer layer 13 far from the thin film transistor layer 12. And the support column 30 is not set in the area corresponding to the fourth spacer structure 144.

The forward projection of the second opening 1302 on the first substrate 11, the forward projection of the third spacer structure 143 on the first substrate 11, and the forward projection of the fourth spacer structure 144 on the first substrate 11 are all located within the forward projection of the black matrix layer 22 on the first substrate 11. Among them, the aperture of the second opening 1302 on the side near the third spacer structure 143 is smaller than the width of the third spacer structure 143 in the direction parallel to the first substrate 11.

The first electrode layer 16 comprises a second electrode 162, and the second electrode layer 171 comprises a fourth electrode. And one end of the second drain 1225 passes through the sixth spacer layer insulation layer 128, the fifth spacer layer insulation layer 127, and the fourth spacer layer insulation layer 126 and is connected to the second active layer 1221, while the other end extends to the surface of the third spacer structure 143 far from the thin film transistor layer 12, and one end of the second electrode 162 extends to the second opening 1302 and is connected to the second drain 1225, The other end extends into the second sub-pixel region 1012 corresponding to the second thin film transistor 122, which can be reused as a pixel electrode. And the fourth spacer structure 144 is filled with a portion of the first opening 1301, covering the second electrode 162 in the second opening 1302, that is, the fourth spacer structure 144 is located on the side of the second electrode 162 away from the first substrate 11.

It is noted that the color blocking block 1311 located in the second sub-pixel region 1012 is also filled in the contact hole between the second drain 1225 and the second active layer 1221 to avoid the appearance of a concave film layer morphology at the contact hole.

It is understood that, in the embodiment of the present disclosure, due to the arrangement of the first spacer structure 141 and the third spacer structure 143, the depth of the first opening 1301 and the second opening 1302 can be reduced, thereby reducing the probability of fracture of the first electrode 161 and the second electrode 162 due to the longer overlap distance.

In one embodiment of the present disclosure, a color of color blocking block 1311 in the first sub-pixel region 1011 is blue, and a color of color blocking block 1311 in the second sub-pixel region 1012 is red or green. Compared to materials with red and green color barriers, materials with blue color barriers are less prone to exposure and development. Therefore, compared to red and green color barriers, larger space is usually reserved on the surrounding area of the corresponding area of the blue color barrier for etching to form a blue color barrier. As the support column 30 also needs to occupy a certain space, a blue color barrier is set in the first sub-pixel region 1011. Furthermore, it is more advantageous to reserve space for setting up support columns 30.

The embodiment of the present disclosure forms a second spacer structure 142 protruding from the surface of the spacer layer 13 after forming the first opening 1301 of the spacer layer 13, and the second spacer structure 142 is correspondingly arranged with the support column 30. Therefore, the film layer around the second spacer structure 142 is further away from the support column 30 in the thickness direction of the display panel, which can prevent the support column 30 from scratching the film layer around the second spacer structure 142 due to movement. Ensuring a yield rate and display effect of the display panel. Furthermore, by setting a first spacer structure 141 below the first opening 1301, the embodiment of the present disclosure can make the depth L1 of the first opening 1301 less than the thickness L2 of the spacer layer 13, reduce the thickness of the second spacer structure 142 during film deposition, avoid the phenomenon of etching residue caused by the thickness of the second spacer structure 142 during film deposition, and further improve the yield rate of the display panel.

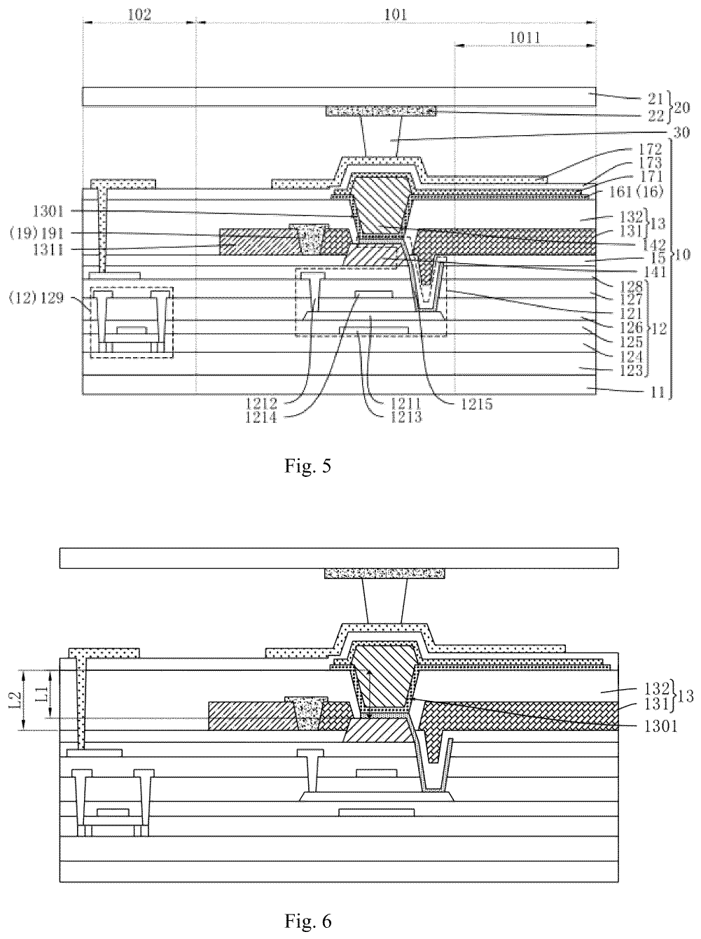

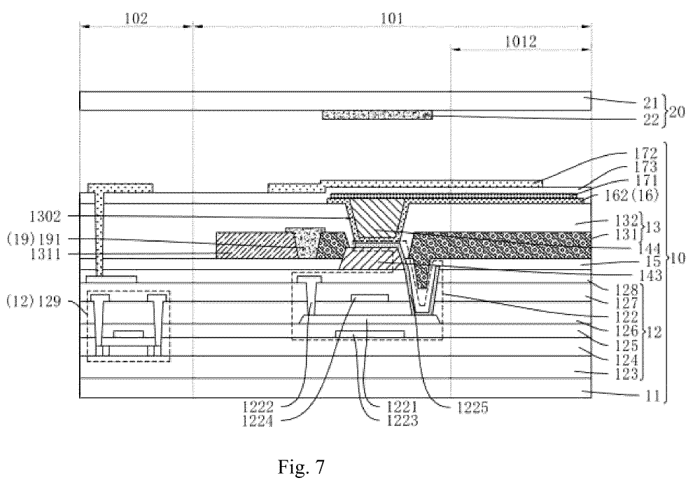

In another embodiment of the present disclosure, please refer to FIGS. 5 to 7. The difference between this embodiment and the embodiments shown in FIGS. 1 to 3 is that the material of the shading layer 19 is the same as that of the black matrix layer 22, and the shading layer 19 comprises a plurality of first shading portions 191 arranged in the first direction X and extending in the second direction Y, while the first shading portion 191 is located in the color blocking layer 131 and between adjacent color blocking blocks 1311, The flat layer 132 covers a plurality of color blocking blocks 1311 and the first shading portion 191.

In this embodiment, the spacer layer 13 comprises a color resistance layer 131 and a flat layer 132. The first opening 1301 is arranged in the flat layer 132, and the second spacer structure 142 is filled in the first opening 1301 and protrudes from the surface of the flat layer 132 on one side away from the thin film transistor layer 12. The second opening 1302 is arranged in the flat layer 132, and the fourth spacer structure 144 is filled in the second opening 1302, which does not exceed the surface of the flat layer 132 on one side away from the thin film transistor layer 12. The first electrode layer 16 is arranged on the surface of the flat layer 132 and extends into the first opening 1301 or the second opening 1302.

It is noted that in this embodiment, the shading layer 19 is set between adjacent color blocking blocks 1311. Compared to the embodiments shown in FIGS. 1, 2, and 3, the setting of the first spacer layer dielectric layer 133 and the second spacer layer dielectric layer 134 can be reduced, and the thickness of the array substrate 10 can be reduced, thereby reducing the thickness of the display panel.

Furthermore, the embodiment of the present disclosure forms a second spacer structure 142 protruding from the surface of the spacer layer 13 after forming the first opening 1301 of the spacer layer 13, and the second spacer structure 142 is correspondingly arranged with the support column 30. Therefore, the film layer around the second spacer structure 142 is further away from the support column 30 in the thickness direction of the display panel, which can prevent the support column 30 from scratching the film layer around the second spacer structure 142 due to movement, Ensuring the yield and display effect of the display panel. Furthermore, by setting a first spacer structure 141 below the first opening 1301, the embodiment of the present disclosure can make the depth L1 of the first opening 1301 less than the thickness L2 of the spacer layer 13, reduce the thickness of the second spacer structure 142 during film deposition, avoid the phenomenon of etching residue caused by the thickness of the second spacer structure 142 during film deposition, and further improve the yield rate of the display panel.

In addition, the present disclosure embodiment provides a display device, which comprises a display panel as described in the above embodiment.

In one embodiment, the display device may also include a backlight module, and the display panel is arranged on the output side of the backlight module.

Since the display device provided by the embodiment of the present disclosure comprises the same display panel as provided the above embodiments, the display device provided by the embodiment of the present application has the same beneficial effects as the display panel described in the above embodiment, which will not be discussed again.

In one embodiment, the display device may include a mobile phone, a television, a tablet, a computer or a Virtual Reality (VR) device.

In the above embodiments, each embodiment is described with its own emphasis. For parts that are not described in detail in a certain embodiment, please refer to the relevant descriptions of other embodiments.

The above has introduced in detail a display panel and display device and provided by the embodiments of the present disclosure. This article uses specific examples to illustrate the principles and implementation methods of the present disclosure. The description of the above embodiments is only used to help understand the present disclosure. The application method and its core idea; at the same time, for those skilled in the art, there will be changes in the specific implementation and application scope based on the ideas of this application. In summary, the contents of this specification should not be understood as limitations on this application.

What is claimed is:

1. A display panel, comprising:
an array substrate;
an opposed substrate, arranged opposite to the array substrate; and
a support column, disposed between the array substrate and the opposed substrate;
wherein, the array substrate comprises:
a first substrate;
a thin film transistor layer, arranged on one side of the first substrate near the opposed substrate;
a first spacer structure, arranged on one side of the thin film transistor layer near the opposed substrate;
a spacer layer, arranged on the side of the first spacer structure near the opposed substrate, wherein a first opening is defined in the spacer layer and located on the side of the first spacer structure near the opposed substrate; and
a second spacer structure, filled in the first opening and protrudes from a surface of the spacer layer, which is near the opposed substrate;
wherein the support column is disposed between the opposed substrate and the second spacer structure, and a depth of the first opening is less than a thickness of the spacer layer.

2. The display panel as claimed in claim 1, wherein the spacer layer comprises a color resistance layer located on one side of the thin film transistor layer away from the first substrate and a flat layer covering the color resistance layer, the color resistance layer comprises a plurality of color resistance blocks, the first spacer structure and the second spacer structure are disposed between adjacent the color resistance blocks, and the first opening is defined in the flat layer.

3. The display panel as claimed in claim 2, wherein the opposed substrate comprises a second substrate and a black matrix layer arranged on one side of the second substrate near the array substrate, the first spacer structure and the second spacer structure are orthogonally projected on the second substrate within a projection of the black matrix layer on the second substrate.

4. The display panel as claimed in claim 3, wherein the support column is located on one side of the black matrix layer away from the second substrate and disposed between the black matrix layer and the second spacer structure.

5. The display panel as claimed in claim 3, wherein the array substrate further comprises a light shielding layer arranged on one side of the color resistance layer away from the thin film transistor layer, the light shielding layer comprises a plurality of first light shielding portions arranged in a first direction and extending in a second direction, and the first direction intersects with the second direction, the black matrix layer comprises a plurality of second shading portions arranged in the second direction and extending in the first direction, and a plurality of first shading portions intersect with a plurality of second shading portions to define a plurality of sub-pixel regions, a plurality of color blocking blocks are arranged within a plurality of sub-pixel regions.

6. The display panel as claimed in claim 5, wherein a material of a shading layer is conductive material, or the material of the shading layer is the same as a material of the black matrix layer.

7. The display panel as claimed in claim 5, wherein the thin film transistor layer comprises a plurality of data lines arranged in the first direction and extending in the second direction, and a plurality of scanning lines arranged in the second direction and extending in the first direction, and a forward projection of the data lines on the first substrate is located within a forward projection of the first shading portion on the first substrate, a forward projection of the scanning line on the first substrate is located within a forward projection of the second shading portion on the first substrate.

8. The display panel as claimed in claim 5, wherein the array substrate further comprises a third spacer structure disposed between the thin film transistor layer and the spacer layer, a second opening opened in the spacer layer and located on one side near the opposed substrate of the third spacer structure, and a fourth spacer structure, and the fourth spacer structure is filled in the second opening, a surface of the fourth spacer structure near the opposed substrate side does not exceed the surface of the spacer layer near the opposed substrate side.

9. The display panel as claimed in claim 8, wherein the thin film transistor layer further comprises a plurality of thin film transistors arranged on the first substrate and corresponding to a plurality of sub-pixel regions, the thin film transistors comprises a first thin film transistor, the first thin film transistor comprises a first active layer, a first gate, and a first source and a first drain respectively connected to both sides of the first active layer, and one end of the first drain is connected to the first active layer, and the other end extends to the surface of the first spacer structure on one side away from the first substrate.

10. The display panel as claimed in claim 9, wherein the thin film transistors further comprises a second thin film transistor, the second thin film transistor comprises a second active layer, a third gate, and a second source and a second drain respectively connected to both sides of the second active layer, and one end of the second drain is connected to the second active layer, and the other end extends to the surface of the third spacer structure on one side away from the first substrate.

11. The display panel as claimed in claim 10, wherein the array substrate further comprises a first electrode layer located on the side of the spacer layer far from the thin film transistor layer, the first electrode layer comprises a first electrode connected to the first thin film transistor and a second electrode connected to the second thin film transistor, each of the sub-pixel regions comprises a first sub-pixel region corresponding to the first thin film transistor, and a second sub-pixel region corresponding to the second thin film transistor; one end of the first electrode extends into the first opening and is connected to the first drain electrode, the other end extends into the first sub-pixel region, and the second spacer structure is located on the side of the first electrode away from the first substrate; and
one end of the second electrode extends into the second opening and is connected to the second drain electrode, while the other end extends into the second sub-pixel region, and the fourth spacer structure is located on the side of the second electrode away from the first substrate.

12. The display panel as claimed in claim 11, wherein a color of the color blocking block in the first sub-pixel region is blue, and the color of the color blocking block in the second sub-pixel region is red or green.

13. The display panel as claimed in claim 11, wherein the array substrate further comprises:
a second electrode layer, is arranged on the side of the first electrode layer far from the spacer layer;
an insulation layer, is arranged on the side of the second electrode layer away from the first electrode layer;
a third electrode layer, is arranged on the side of the insulation layer away from the second electrode layer;
wherein, the first electrode layer is connected to the second electrode layer and forms a storage capacitor structure with the third electrode layer.

14. The display panel as claimed in claim 2, wherein the spacer layer covers a portion of the first spacer structure, and an aperture of the first opening near the first spacer structure on one side is smaller than a width of the first spacer structure in a direction parallel to the first substrate, and the first opening is spaced apart from the color blocking block.

15. The display panel as claimed in claim 1, wherein both a material of the first spacer structure and a material of the second spacer structure comprise organic materials.

16. A display device, comprising a backlight module and a display panel disposed on an emitting light side of the backlight module, the display panel, comprising:
an array substrate;
an opposed substrate, arranged opposite to the array substrate; and
a support column, disposed between the array substrate and the opposed substrate;
wherein the array substrate comprises:
a first substrate;
a thin film transistor layer, arranged on one side of the first substrate near the opposed substrate;
a first spacer structure, arranged on one side of the thin film transistor layer near the opposed substrate;
a spacer layer, arranged on the side of the first spacer structure near the opposed substrate, wherein a first opening is defined in the spacer layer and located on the side of the first spacer structure near the opposed substrate; and
a second spacer structure, filled in the first opening and protrudes from a surface of the spacer layer, which is near the opposed substrate;
wherein the support column is disposed between the opposed substrate and the second spacer structure, and a depth of the first opening is less than a thickness of the spacer layer.

17. The display device as claimed in claim 16, wherein the spacer layer comprises a color resistance layer located on one side of the thin film transistor layer away from the first substrate and a flat layer covering the color resistance layer, the color resistance layer comprises a plurality of color resistance blocks, the first spacer structure and the second spacer structure are disposed between adjacent the color resistance blocks, and the first opening is defined in the flat layer.

18. The display device as claimed in claim 17, wherein the opposed substrate comprises a second substrate and a black matrix layer arranged on one side of the second substrate near the array substrate, the first spacer structure and the second spacer structure are orthogonally projected on the second substrate within a projection of the black matrix layer on the second substrate.

19. The display device as claimed in claim 17, wherein the spacer layer covers a portion of the first spacer structure, and an aperture of the first opening near the first spacer structure on one side is smaller than a width of the first spacer structure in a direction parallel to the first substrate, and the first opening is spaced apart from the color blocking block.

20. The display device as claimed in claim 16, wherein a material of the first spacer structure and a material of the second spacer structure comprise organic materials.
